(19) United States
(12) Patent Application Publication
(10) Pub. No.: US 2011/0079920 A1
(43) Pub. Date: Apr. 7, 2011

(54) ELECTRICAL CONNECTION VIA FOR THE SUBSTRATE OF A SEMICONDUCTOR DEVICE

(75) Inventors: Hamed Chaabouni, Grenoble (FR); Lionel Cadix, Grenoble (FR)

(73) Assignee: STMICROELECTRONICS (CROLLES 2) SAS, Crolles Cedex (FR)

(21) Appl. No.: 12/897,462

(22) Filed: Oct. 4, 2010

(30) Foreign Application Priority Data
Oct. 5, 2009 (FR) 0956931

(51) Int. Cl. H01L 23/48; H01L 21/768; H01L 21/44

(52) U.S. Cl. 257/774; 438/675; 438/597; 257/E23.011; 257/E21.577; 257/E21.476

(57) ABSTRACT

An electrical connection via is formed through a substrate to make an electrical connection from one face of the substrate to the other. The via includes a ring made of an electrically conductive material. The ring is formed in a hole in the substrate so as to at least partly form the via.

### PRIORITY CLAIM

This application claims priority from French Application for Patent No. 09-56931 filed Oct. 5, 2009, the disclosure of which is hereby incorporated by reference.

### TECHNICAL FIELD

The present invention relates to the field of semiconductor devices.

### BACKGROUND

Since semiconductor devices are becoming increasingly complex, it may be advantageous to produce electrical connections through substrates, generally made of silicon, on which they are produced, so as to make electrical connections from one face to another face of the substrate.

### SUMMARY

What is proposed is a process for producing an electrical connection via through a substrate in order to make an electrical connection from one face of the substrate to another face of the substrate.

The process may comprise the production of a hole in the substrate and the production in this hole of at least one ring made of an electrically conductive material at least partly forming the via.

The process may comprise the production of an intermediate ring made of an insulating material against the peripheral wall of the hole in the substrate before said conducting ring is produced.

The process may comprise the production, in the hole in the substrate, of at least two rings made of an electrically conductive material by producing, between them, an intermediate ring made of an insulating material, these rings at least partly forming said via.

The process may comprise the production of an inner ring made of an insulating material in the hole of a conducting ring and the production of a central cylinder made of an electrically conductive material, so as to obtain, in the hole in the substrate, a via comprising, coaxially, this conducting cylinder and at least one conducting ring.

The radial thickness (e) of the wall of each conducting ring may be chosen to be at most twice the skin depth (δ) in the material forming the via.

The diameter of the conducting central cylinder may be chosen to be at most twice the skin depth (δ) in the material forming the via.

Also proposed is a substrate for a semiconductor device, comprising at least one via for electrical connection from one face to the other, made of an electrically conductive material.

The electrical connection via may comprise at least one conducting ring made in a hole passing through the substrate.

The electrical connection via may comprise at least two coaxial rings made of an electrically conductive material, these being separated by a ring made of an insulating material, these rings being made in the hole passing through the substrate.

The electrical connection via may comprise a central cylinder made of an electrically conductive material, surrounded by an insulating ring.

The radial thickness (e) of the wall of each electrically conducting ring may be at most twice the skin depth (δ) in the material forming the via. The diameter of the conducting central cylinder is at most twice the skin depth (δ) in the material forming the via.

Also proposed is a substrate for a semiconductor device, comprising at least one via for electrical connection from one face to the other, made of an electrically conductive material, each portion of this via having a thickness at most twice the skin depth (δ) in the material forming the via.

Also proposed is a semiconductor device comprising a substrate as defined above and, on one face of this substrate, an integrated circuit connected to said via.

### BRIEF DESCRIPTION OF THE DRAWINGS

Semiconductor devices will now be described by way of non-limiting examples and illustrated by the drawing in which:

FIG. 1 shows a partial transverse section of a semiconductor device, in the zone of an electrical connection via;

FIG. 2 shows a section on the line II-II of the semiconductor device of FIG. 1;

FIGS. 3 to 13 show transverse sections of the semiconductor device of FIG. 1 according to successive fabrication steps;

FIG. 14 shows a partial transverse section of a semiconductor device in the zone of another electrical connection via, according to a fabrication step; and

FIGS. 15 to 18 show a section of the semiconductor device of FIG. 14 according to fabrication steps.

### DETAILED DESCRIPTION OF THE DRAWINGS

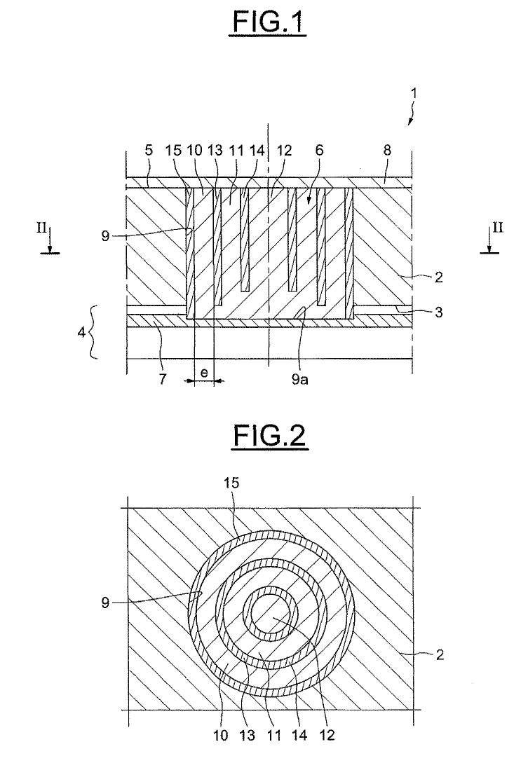

According to one embodiment, illustrated in FIGS. 1 and 2, a semiconductor device 1 comprises a substrate 2, in the form of a wafer, for example a silicon wafer, on a front face 3 of which are produced, in a front layer 4, integrated circuits and interconnect means.

To produce for example an electrical connection of these integrated circuits between the front face 3 and the rear face 5 of the substrate 2, in one direction or the other, said substrate is traversed by an electrical connection via 6 so as, for example, to provide a link between a front pad 7 of the interconnect means of the front layer 4 and a rear pad 8 of interconnect means made on the rear face 5 of the substrate 2, the front pad 7 being for example in the first metal level of the interconnect means.

The electrical connection via 6 is made in a hole 9, for example a cylindrical hole, passing through the substrate 2.

The electrical connection via 6 may comprise, coaxially with this hole 9, at least one ring made of an electrically conductive material or a plurality of rings that are separated by rings made of an insulating material and optionally a central cylinder separated from the adjacent ring by a ring made of an insulating material.

According to the example shown, the electrical connection via 6 comprises a conducting outer cylindrical ring 10 and a conducting inner cylindrical ring 11, together with a conducting central cylinder 12. The outer conducting ring 10 and the inner conducting ring 11 are separated by an insulating ring 13, and the inner conducting ring and the conducting central cylinder 12 are separated by an insulating ring 14.

In addition, an insulating intermediate ring 15 may optionally be inserted between the wall of the through-hole 9 and the outer conducting ring 10.

The electrical connection via 6 may be produced by employing any suitable known means commonly used in microelectronics, for example in the following manner.

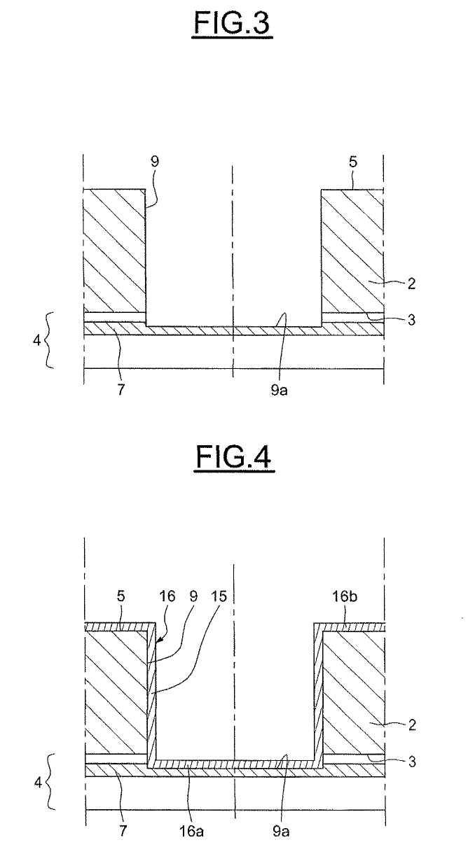

As shown in FIG. 3, for a substrate 2 provided with the front layer 4, the cylindrical hole 9 is produced for example by etching. The hole 9 has a bottom 9a on the front pad 7 or slightly set into this pad.

Next, as shown in FIG. 4, an insulating layer 16 is deposited. This layer 16 covers the wall of the cylindrical hole 9 in order to form the insulating intermediate ring 15 and has a portion 16a covering the bottom 9a of the cylindrical hole 9 and a portion 16b covering the front face 5 of the substrate 2.

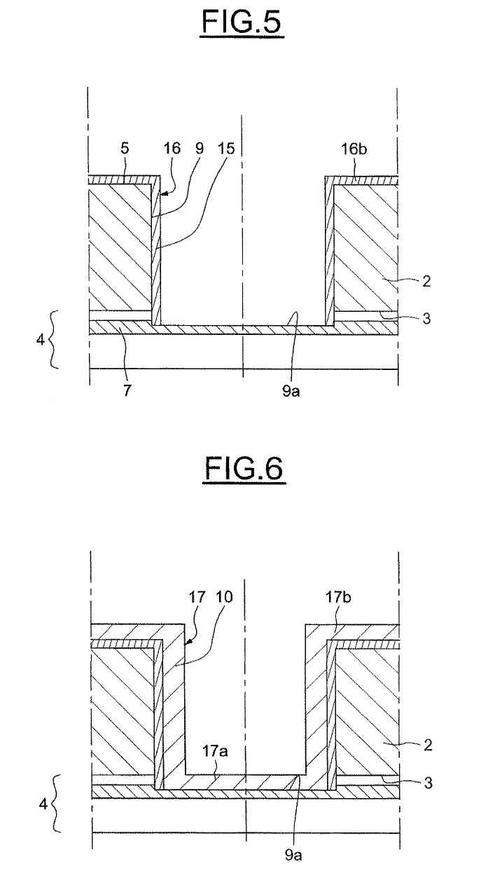

Next, as shown in FIG. 5, the portion 16a of the layer 16 is removed so as to expose the front pad 7.

Next, as shown in FIG. 6, a conducting layer 17 is deposited. This layer 17 covers the inner wall of the insulating intermediate ring 15 in order to form the outer conducting ring 10 and has a portion 17a covering the bottom 9a of the hole, i.e. covering the front pad 7, and a portion 17b covering the portion 16b of the insulating layer 16.

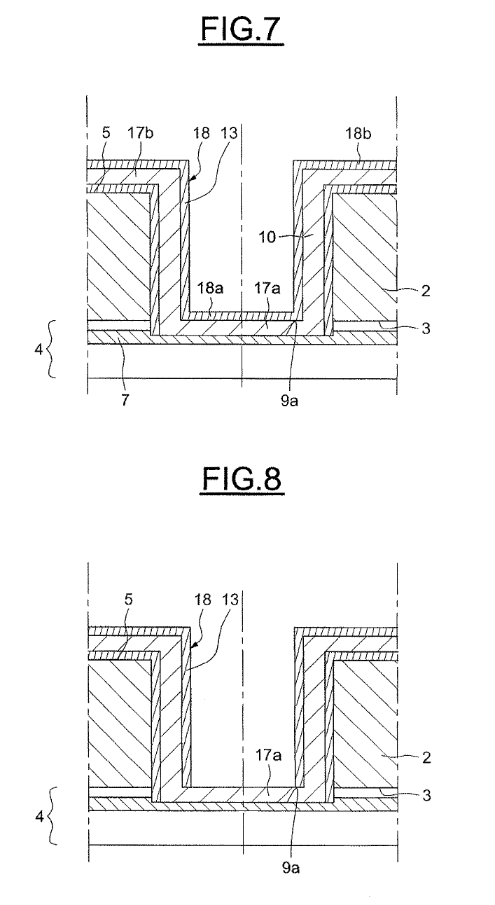

Next, as shown in FIG. 7, an insulating layer 18 is deposited. This layer 18 covers the inner wall of the outer conducting ring 10 in order to form the insulating ring 13 and has a portion 18a covering the bottom of the hole in the layer 17, i.e. covering the portion 17a of this layer 17, and a portion 18b covering the portion 17b of the conducting layer 17.

Next, as shown in FIG. 8, the portion 18a of the insulating layer 18 is removed so as to expose the front pad 7.

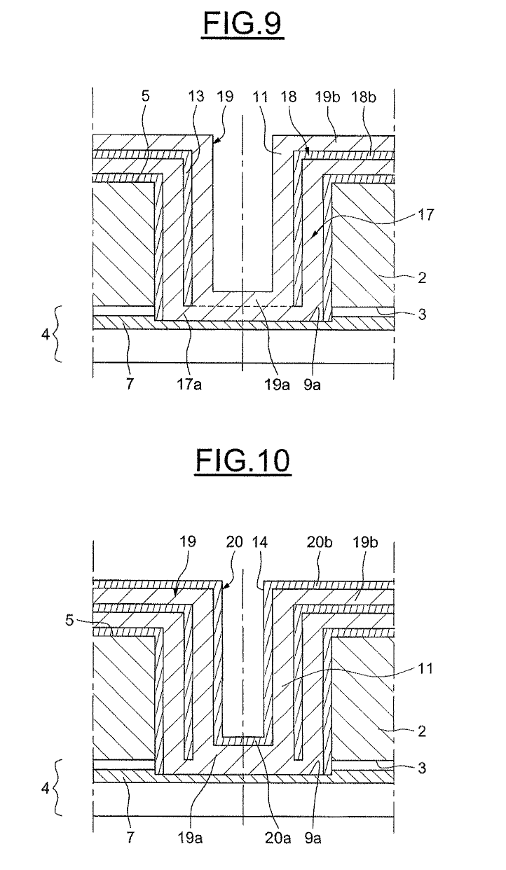

Next, as shown in FIG. 9, a conducting layer 19 is deposited, as described above with regard to FIG. 6. This layer 19 covers the inner wall of the insulating ring 13 so as to form the inner conducting ring 11 and has a portion 19a covering the bottom of the hole, i.e. covering the portion 17a of the layer 17, and a portion 19b covering the portion 18b of the insulating layer 18.

Next, as shown in FIG. 10, an insulating layer 20 is deposited, as described above with regard to FIG. 7. This layer 20 covers the inner wall of the inner conducting ring 11 so as to form the insulating ring 14 and has a portion 20a, covering the bottom of the hole in the layer 19, i.e. covering the portion 17a of this layer 17, and a portion 20b covering the portion 19b of the conducting layer 19.

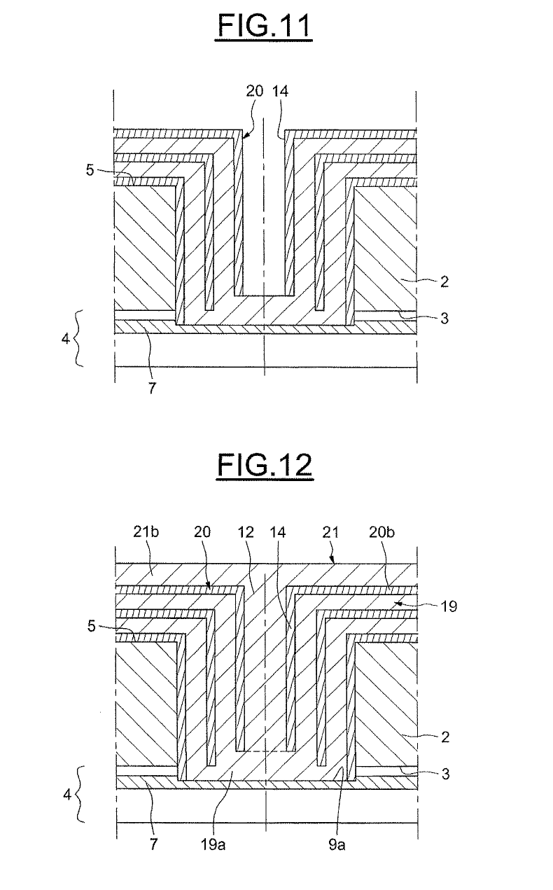

Next, as shown in FIG. 11, the portion 20a of the insulating layer 20 is removed so as to expose the portion 19a of the conducting layer 19, as described above with regard to FIG. 8.

Next, as shown in FIG. 12, a conducting layer 21 is deposited. This layer 19 fills the hole left in the insulating ring 14, on top of the portion 19a of the conducting layer 19, so as to form the conducting central cylinder 12, and has a portion 21b that covers the portion 20b of the insulating layer 20.

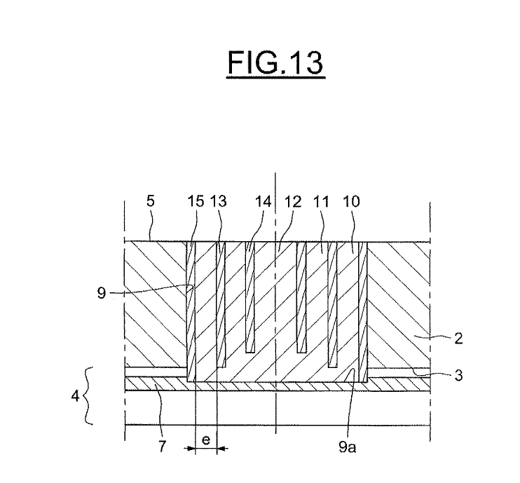

Next, as shown in FIG. 13, the portions 16b, 17b, 18b, 19b, 20b and 21b of the corresponding layers are removed, for example by CMP (chemical-mechanical polishing), so as to expose the rear face 5 of the substrate 2 and form the rear radial face 12 of the electrical connection via 6.

Thus, the rings 10, 11, 13, 14 and 15 and the central cylinder 12 have rear radial faces lying in the plane of the rear face 5 of the substrate 2.

On the front side, the front radial face of the intermediate ring 15 is on the front pad 7 and the front radial faces of the insulating rings 13 and 14 are at a certain distance from the front pad 7 in such a way that the conducting rings 10 and 11 and the conducting central cylinder 12 meet between the front radial faces of the insulating rings 13 and 14 and the front pad 7.

Of course, a plurality of electrical connection vias 6 may be produced at the same time.

Next, the rear interconnect means may be produced on the rear face 5 of the substrate 2, these means comprising the rear pad 8 on the electrical connection via 6.

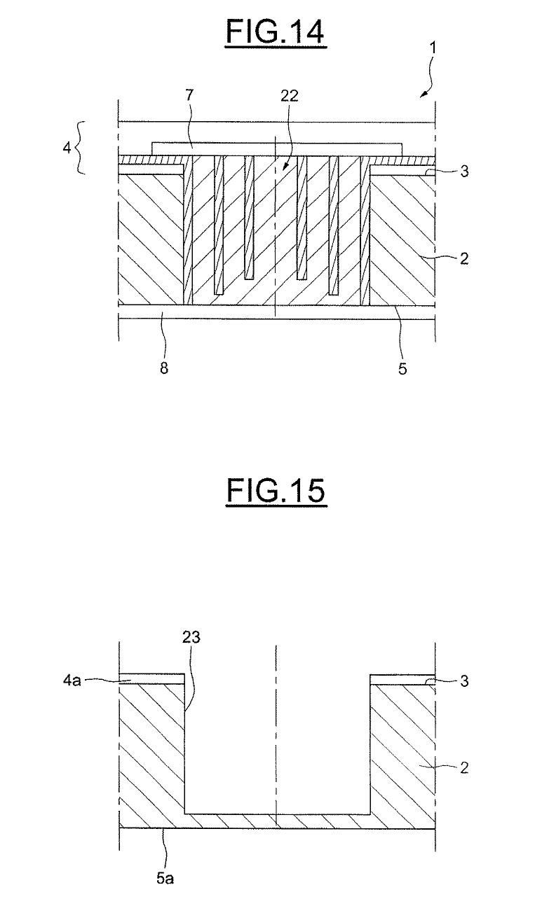

According to an alternative embodiment, illustrated in FIG. 14, a semiconductor device 1 comprises an electrical connection via 22, connecting a front pad 7 of a front layer 4 to a rear pad 8, which via may be produced on the side of the front face 3 of the substrate 2. As shown, this via 22 corresponds substantially to the via 6 of the example described previously.

The electrical connection via 22 may be produced in the following manner.

As shown in FIG. 15, starting with a thick substrate 2, integrated circuits are produced on its front face 3, forming a sublayer 4a.

Next, a blind cylindrical hole 23 is produced through the sublayer 4a and into the substrate 2, without this hole reaching the rear face 5a of the substrate 2. The blind cylindrical hole 23 is of course produced in a zone of the sublayer 4a that is free of integrated circuits.

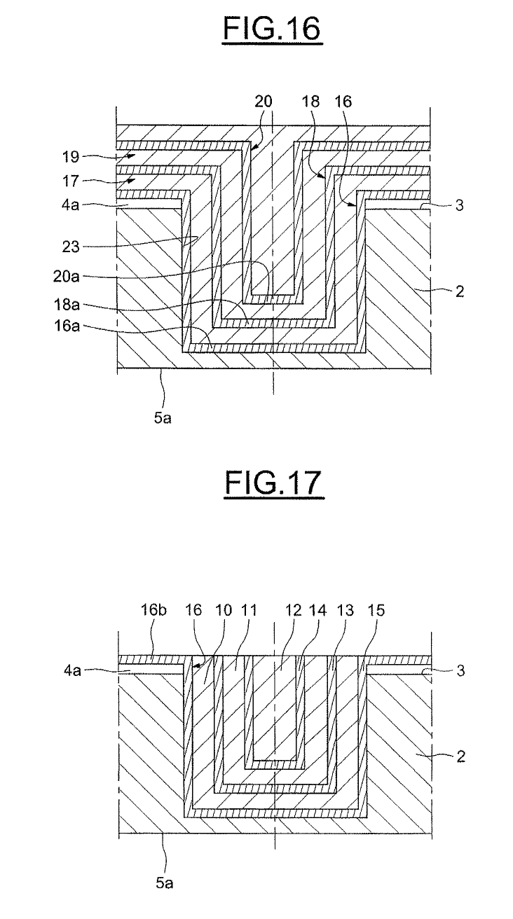

Next, as shown in FIG. 16, the electrical connection via is produced in the hole 23, according to the steps for producing the electrical connection via 6, as described with reference to FIGS. 4, 6, 7, 9, 10 and 12, i.e. without removing the portions 16a, 18a and 20a of the insulating layers 16, 18 and 20 located respectively at the bottom of the hole 23 and of the holes in the conducting layers 17 and 19.

Next, as shown in FIG. 17, a chemical-mechanical polishing (CMP) operation is carried out, on the face 3 side of the substrate 2, down to the portion 16b of the layer 16, making the front faces of the conducting rings 10, 11 and 12 and the front faces of the insulating rings 13, 14 and 15 lie in the same plane.

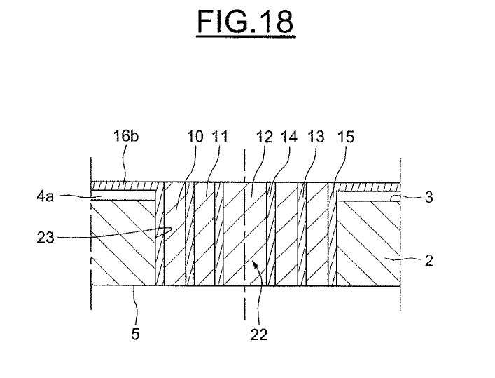

Next, as also illustrated in FIG. 18, the substrate 2 is thinned via its rear face, so as to form rear faces of the conducting rings 10, 11 and 12 and rear faces of the insulating rings 13, 14 and 15 that lie in the same plane as the resulting rear face 5 of the substrate 2. The electrical connection via 22 is therefore produced.

Thereafter, the interconnect means may be produced on the portion 16a in order to complete and form the layer 4, including the front pad 7 on the front faces of the conducting rings 10, 11 and 12 and of the insulating rings 13, 14 and 15, and to produce the interconnect means on the rear face 5, including the rear pad 8 on the rear faces of the conducting rings 10, 11 and 12 and of the insulating rings 13, 14 and 15.

In an alternative embodiment, the layer 4 could be completed and formed before the substrate 2 is thinned.

The structures of the electrical connection vias that have been described above may be particularly advantageous because they may be designed to reduce the skin effects in the material constituting them, or even for eliminating said effects, while limiting the electrical resistance of the vias. This enables the joule losses to be limited.

The skin depth is used to determine the width of the zone in which the current is concentrated in an electrical conductor. This depth enables the effective resistance at a given frequency to be calculated.

The skin depth is generally calculated by applying the following formula (A):

$$δ = \sqrt{\frac{2}{ωμσ}} = \sqrt{\frac{2 ρ}{ωμ}} ,$$

in which:
δ represents the skin depth in metres;
ω represents the angular frequency in radians per second (i.e. ω=2πf);
f represents the frequency of the current in hertz;
μ represents the magnetic permeability in henries per metre;
ρ represents the resistivity in ohms-metre (i.e. ρ=1/σ); and
σ represents the electrical conductivity in siemens per metre.

Thus, having chosen a material for producing the electrical connection via of the examples described, the skin depth δ may be calculated according to the characteristics of this material and of the current that has to pass through the via, by applying the above formula (A).

After this, a maximum thickness e attributed to the walls of said conducting rings and a diameter of said conducting central cylinder forming the electrical connection vias 6 and 22 of the examples described may be chosen in such a way that this thickness e is at most equal to twice the calculated skin depth δ.

The present invention is not limited to the examples described above. Many other alternative embodiments are possible, for example by choosing a different number of rings, without departing from the scope defined by the appended claims.

What is claimed is:

1. A process, comprising:
producing a hole in a substrate;
producing in the hole of at least one ring made of an electrically conductive material at least partly forming an electrical connection via through the substrate in order to make an electrical connection from one face of the substrate to another face of the substrate.

2. The process according to claim 1, further comprising:
producing against a peripheral wall of the hole in the substrate, before producing the at least one ring made of the electrically conductive material, an intermediate ring made of an insulating material.

3. The process according to claim 1, wherein producing at least one ring comprises producing, in the hole of the substrate, at least two rings made of the electrically conductive material; and
producing, between the two rings, an intermediate ring made of an insulating material;
wherein the at least two rings at least partly form said electrical connection via.

4. The process according to claim 1, further comprising:
producing, against a peripheral wall of the at least one ring made of an electrically conductive material, an inner ring made of an insulating material; and
producing a central cylinder made of the electrically conductive material,
so as to obtain, in the hole in the substrate, a via comprising, coaxially, the conducting cylinder and the at least one conducting ring.

5. The process according to claim 1, wherein a radial thickness (e) of a wall of each conducting ring is at most twice a skin depth (δ) in the material forming the via.

6. The process according to claim 4, wherein a diameter of the conducting central cylinder is at most twice a skin depth (δ) in the material forming the via.

7. The process according to claim 1 wherein the hole in the substrate is a cylindrical aperture.

8. The process according to claim 7 wherein the hole extends from a first side of the substrate to a second side of the substrate and terminates at a conductive layer on the first side of the substrate, the at least one ring made of an electrically conductive material contacting the conductive layer.

9. The process according to claim 7, wherein the hole is a blind cylindrical aperture extending from a first side of the substrate, the process further comprising thinning the substrate from a second side of the substrate to reach a depth of the blind cylindrical aperture.

10. Apparatus, comprising:
a substrate of a semiconductor device;
at least one via providing an electrical connection from one face to another face of the substrate;
wherein the via is made of an electrically conductive material;
wherein the via comprises at least one conducting ring made in a hole passing through the substrate.

11. The apparatus according to claim 10, wherein said via comprises at least two coaxial rings made of the electrically conductive material, the coaxial rings being separated by a ring made of an insulating material, the coaxial rings being made in the hole passing through the substrate.

12. The apparatus according to claim 10, wherein said via further comprises a central cylinder made of the electrically conductive material, and an insulating ring surrounding the central cylinder.

13. The apparatus according to claim 10, wherein a radial thickness of a wall of each electrically conducting ring is at most twice a skin depth (δ) in the material forming the via.

14. The apparatus according to claim 12, wherein a diameter of the conducting central cylinder is at most twice a skin depth (δ) in the material forming the via.

15. The apparatus of claim 10, further comprising, on one face of the substrate, an integrated circuit connected to said via.

16. Apparatus, comprising:
a substrate of a semiconductor device;
at least one via providing an electrical connection from one face of the substrate to another face of the substrate,
wherein the via is made of an electrically conductive material,
wherein each portion of the via has a thickness at most twice a skin depth in the material forming the via.

17. The apparatus of claim 16, further comprising, on one face of the substrate, an integrated circuit connected to said via.

18. A process, comprising:
forming a cylindrical aperture in a substrate;
forming within the cylindrical aperture a first annular layer of insulating material;
forming on an inner peripheral wall of the first annular layer of insulating material a first annular layer of conductive material.

19. The process according to claim 18, wherein the cylindrical aperture is a blind cylindrical aperture extending from a first side of the substrate.

20. The process according to claim 19, further comprising thinning the substrate from a second side of the substrate opposite the first side so as to expose a bottom of the first annular layer of insulating material and first annular layer of conductive material.

21. The process according to claim 18, wherein forming the cylindrical aperture in the substrate comprises forming the cylindrical aperture to extend from a first side of the substrate to a second side of the substrate and terminate at a conductive layer on the first side of the substrate, and wherein forming the first annular layer of conductive material comprises forming the first annular layer of conductive material to be in contact with the conductive layer.

22. The process according to claim 18, further comprising:
forming on an inner peripheral wall of the first annular layer of conductive material a second annular layer of insulating material; and
forming on an inner peripheral wall of the insulating material second layer a second annular layer of conductive material.

23. The process according to claim 22, wherein forming the cylindrical aperture in the substrate comprises forming the cylindrical aperture to extend from a first side of the substrate to a second side of the substrate and terminate at a conductive layer on the first side of the substrate, wherein forming the first annular layer of conductive material and forming the second annular layer of conductive material comprises forming these annular layers to be in contact with the conductive layer.

24. The process according to claim 23, wherein forming the second annular layer of insulating material comprises forming the second annular layer of insulating material to not be in contact with the conductive layer.

25. The process according to claim 18, further comprising:
forming in the cylindrical aperture in a substrate a central cylinder made of the electrically conductive material, and
forming an annular insulating ring surrounding the central cylinder.

26. The process according to claim 25, wherein forming the cylindrical aperture in the substrate comprises forming the cylindrical aperture to extend from a first side of the substrate to a second side of the substrate and terminate at a conductive layer on the first side of the substrate, wherein forming the first annular layer of conductive material and forming the central cylinder of conductive material comprises forming the first annular layer and central cylinder to be in contact with the conductive layer.

27. The process according to claim 26, wherein forming the annular insulating ring surrounding the central cylinder comprises forming the annular insulating ring surrounding the central cylinder to not be in contact with the conductive layer.
